(19) United States
(12) Patent Application Publication
(10) Pub. No.: US 2015/0293153 A1
(43) Pub. Date: Oct. 15, 2015

(54) FLUXGATE CURRENT SENSOR

(71) Applicant: VACUUMSCHMELZE GMBH & CO. KG, Hanau (DE)

(72) Inventors: Steffen BOETTCHER, Kahl (DE); Holger SCHWENK, Hanau (DE)

(21) Appl. No.: 14/300,950

(22) Filed: Jun. 10, 2014

(30) Foreign Application Priority Data
Apr. 14, 2014 (DE) 102014105306.0

(51) Int. Cl. G01R 15/18; G01R 19/00

(52) U.S. Cl. CPC G01R 15/185; G01R 19/0092

(57) ABSTRACT

A current sensor arrangement for measuring an effective primary current in a primary conductor is described. The current sensor arrangement comprises a magnetic core for the magnetic connection of the primary conductor to a secondary conductor, as well as a controlled voltage source that is connected to the secondary conductor and configured to apply a voltage with adjustable polarity to the secondary conductor. As a result of this, a secondary current flows through the secondary conductor. A measurement and control unit connected to the secondary conductor is configured to generate a measurement signal representing a secondary current and to continuously detect the achievement of a magnetic saturation in the core. In the case of detection of a magnetic saturation of the core, the polarity of the voltage is reversed in order to reversely magnetize the core. Moreover, the measurement and control unit is configured to sample the measurement signal after a delay time following the detection of a magnetic saturation of the core. This delay time is adjusted adaptively depending on a previously determined time period between two successive times when magnetic saturation of the core has been detected.

This application claims benefit of the filing date of DE 10 2014 105 306.0, filed 14 Apr. 2014, the contents of which are incorporated herein by reference for all purposes.

### BACKGROUND

1. Technical Field

The present disclosure relates to a fluxgate current sensor; for example, a differential current sensor for use in residual-current circuit breakers.

2. Description of Related Art

For contact-free and thus potential-free measurement of the intensity of an electrical current in a conductor, so-called “open-loop current sensors” are used, which detect the magnetic flux generated by the current (by means of a Hall sensor in a split (i.e. having an air gap) magnetic circuit, for example) and generate a signal proportional to the current's intensity. These sensors are very cost-effective, but their precision is relatively low. Direct-imaging current sensors are open-loop current sensors that do not comprise a closed control circuit.

Moreover, so-called “closed-loop current sensors” are used, in which a magnetically opposing magnetic field of identical magnitude to that of the magnetic field of the current to be measured is generated by means of a closed control circuit so that a complete magnetic field compensation is continuously achieved; the magnitude of the current to be measured can be determined from the parameters for generating the opposing field. Closed-loop current sensors thus belong to the class of compensation current sensors.

So-called “fluxgate sensors” are a particular type of compensation current sensor that do not comprise a closed control circuit. Such current sensors include a magnetic core with a primary winding and a secondary winding. A compensation of the magnetic field generated by the current to be measured (primary current) by means of the primary winding occurs only at certain time intervals of a measurement cycle, wherein the magnetic core is driven by the secondary winding into positive and negative saturation in each measurement cycle. A very precise current measurement is therefore possible with such sensors, since it is possible to eliminate the influence of the hysteresis of the magnetic core by using appropriate signal processing. For this reason, fluxgate current sensors are also suitable for the differential current measurement. In this case, the primary winding consists of at least two partial windings; the difference between the currents is measured through the two partial windings. In the simplest case, the two partial windings are straight lines that are passed through a ring core. In the case of more than two partial windings, the currents in the partial windings are subtracted or added depending on the current flow direction and the orientation of the respective partial winding.

In the measurement of differential currents in particular, known methods for determining the primary current difference provide measurement results that are too imprecise for numerous applications. Consequently, there is a need for differential current sensors based on the fluxgate principle that allow for a high-precision differential current measurement.

### SUMMARY

A current sensor arrangement for measuring an effective primary current in a primary conductor is described. According to an example of the invention, the current sensor arrangement comprises a magnetic core for the magnetic coupling of the primary conductor to a secondary conductor, as well as a controlled voltage source that is connected to the secondary conductor and configured to apply a voltage with adjustable polarity to the secondary conductor. Consequently, a secondary current flows through the secondary conductor. A measurement and control unit connected to the secondary conductor is configured to generate a measurement signal representing a secondary current and to continuously detect a magnetic saturation in the core. At the time of the detection of a magnetic saturation of the core, the polarity of the voltage is reversed in order to reversely magnetize the core. The measurement and control unit is moreover configured to sample the measurement signal after a delay time following each detection of a magnetic saturation of the core. This delay time is adjusted adaptively depending on a previously determined time period between two successive times when magnetic saturation of the core has been detected.

A further aspect of the invention relates to a method for measuring a primary current by means of a fluxgate current sensor arrangement, which comprises a primary conductor and a secondary conductor that are magnetically coupled via a magnetic core. According to an example of the invention, the method includes the continuous detection of a magnetic saturation in the core and the switching of the polarity of a supply voltage applied to the secondary conductor when a magnetic saturation has been detected. The time period between two successive detections of a magnetic saturation in the core is determined continuously. A secondary current through the secondary conductor is sampled after the expiration of a delay time after the detection of a magnetic saturation. This delay time is adjusted depending on a previously determined time period between two successive detections of a magnetic saturation in the core.

Another aspect of the invention relates to a differential current sensor, as well as to a residual-current circuit breaker with such a differential current sensor for measuring the difference between a first primary current in a first part and a second primary current in a second part of a primary conductor. According to an example of the invention, the differential current sensor comprises a magnetic core for the magnetic coupling of the primary conductor to a secondary conductor, as well as a controlled voltage source that is connected to the secondary conductor and that is configured to apply a voltage with adjustable polarity to the secondary conductor. As a result, a secondary current flows through the secondary conductor. A measurement and control unit connected to the secondary conductor is configured to generate a measurement signal representing the secondary current and to continuously detect a magnetic saturation in the core. In the case of detection of a magnetic saturation of the core, the polarity of the voltage is reversed in order to reversely magnetize the core. The measurement and control unit is furthermore configured to sample the measurement signals after a delay time following each detection of a magnetic saturation of the core. This delay time is adjusted adaptively depending on a previously determined time period between two successive detections of a magnetic saturation of the core.

### BRIEF EXPLANATION OF THE FIGURES

The invention is further explained below in reference to the examples represented in the figures. The representations are not necessarily true to scale, and the invention is not limited to the represented aspects. Instead, emphasis is placed on representing the principles on which the invention is based.

FIG. 1 is a block diagram of a known current sensor arrangement that operates according to the fluxgate principle.

FIG. 2A and FIG. 2B illustrate the (idealized) signal sequence of the secondary current, magnetization and magnetic field strength of a freely oscillating current sensor arrangement with a primary current of zero.

FIG. 3A and FIG. 3B illustrate the (idealized) signal sequence of the secondary current, magnetization and magnetic field strength of a feely oscillating current sensor arrangement with a primary current greater than zero.

FIG. 4 illustrates a real, measured signal sequence of the secondary current over approximately half of a period of sensor oscillation.

FIG. 5 illustrates a sensor arrangement for measuring a current difference similar to the sensor rearrangement of FIG. 1.

FIG. 6 illustrates an example of a sensor arrangement with adaptive adjustment of the sampling times for the secondary current.

FIG. 7 is based on a time diagram; it illustrates the function of the sensor arrangement of FIG. 6.

FIG. 8 is based on a flow diagram; it illustrates an example of the determination of a primary current, or a primary current difference, from the secondary current.

In the figures, identical reference numerals denote identical or corresponding components with identical or similar meaning

### DETAILED DESCRIPTION

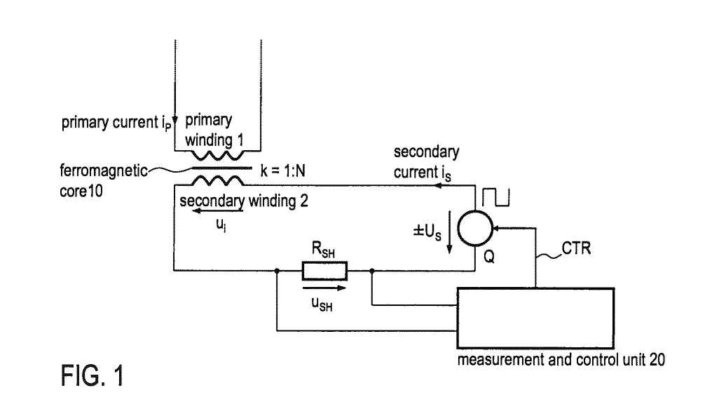

In FIG. 1, which is based on a block diagram, an example of a fluxgate compensation current sensor without a hysteresis error is represented. The current to be measured (primary current iₚ) flows through primary winding 1 (primary conductor), which is magnetically connected, as an example, via soft magnetic unslit core 10 to secondary winding 2 (secondary conductor). Primary winding 1 can consist, for example, of a single winding; i.e., primary winding 1 is formed by a conductor that is passed through core 10 (winding number 1). Secondary winding 2 (winding number N) is series-connected to controlled voltage source Q, which generates secondary current iₛ through the secondary winding. To measure secondary current iₛ, shunt resistor R_{SH} is connected between secondary winding 2 and voltage source Q. Voltage U_{SH} is applied via shunt resistor R_{SH} to measurement and control unit 20, which also provides control signal CTR for actuating controlled voltage source Q.

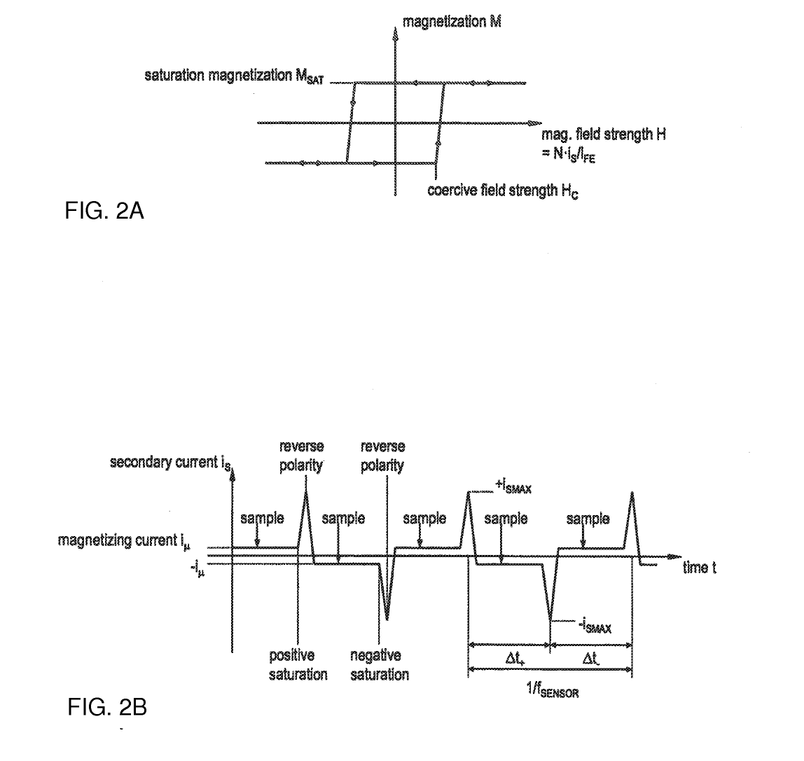

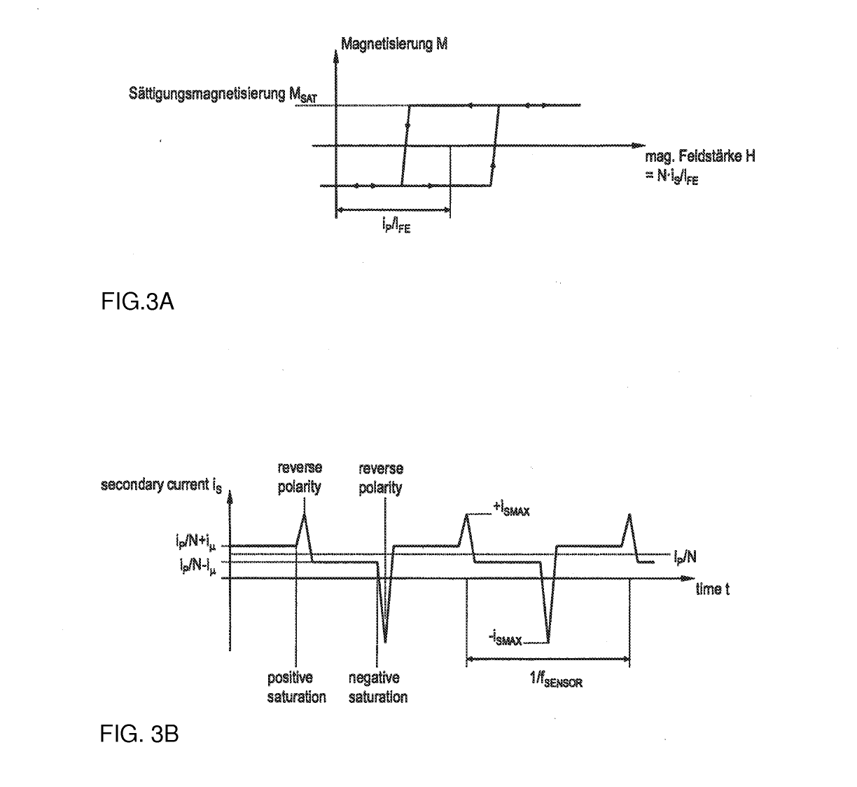

The operating procedure of the current measurement arrangement represented in FIG. 1 is described below in reference to FIGS. 2 and 3. FIG. 2A describes the ferromagnetic properties of magnetic core 10 based on a magnetization characteristic wherein magnetic field strength H is plotted on the abscissa and magnetization M is plotted on the ordinate. The magnetization characteristic has an approximately rectangular hysteresis with a certain coercivity field strength H_{C} and a certain saturation magnetization M_{SAT}. For magnetic field strength H, the simplified formula H=N i_{S}/I_{FE} (in accordance with Ampere's law) is applicable, wherein parameter I_{FE} represents the effective magnetic path length of the magnetic field lines in core 10.

The following equation applies, in accordance with Faraday's law, to voltage u₁ induced in secondary coil 2:

uᵢ=−N·dΦ/dt=−N·A·dB/dt, (1)

wherein parameter A represents the cross-sectional area of core 10, Φ represents the magnetic flux caused by secondary current iₛ through core 10 and B represents the magnetic flux density. Magnetic flux density B can be represented in general by the relation B=μ₀·(H+M); it follows from this that during the remagnetization of core 10 (corresponding to the left or right vertical branch of the magnetization characteristic in FIG. 2A), the change rate of magnetization dM/dt is proportional to induced voltage uᵢ and thus magnetic field strength H and secondary current i_{S} are constant; i.e.,

uᵢ=−N·A·μ₀·dM/dt (during the time of remagnetization). (2)

One can also say that the differential inductivity of secondary coil 2 is almost infinitely large during remagnetization. As soon as the magnetization in core 10 has reached saturation magnetization M_{SAT}, secondary current iₛ increases and is then limited only by the ohmic resistance of secondary winding 2 and shunt resistor R_{SH}.

The increase of secondary current i_{S} is detected by measurement and control unit 20 by means of comparators, for example (see FIG. 2B). As soon as the secondary current has exceeded positive threshold +i_{SMAX} or decreased below negative threshold −i_{SMAX}, measurement and control unit 20 generates corresponding control signal CTR in order to switch the polarity of voltage source Q and initiate the next remagnetization cycle.

The temporal course of the secondary current, if primary current i_{P} is zero, is represented in FIG. 2B. During remagnetization (see the approximately vertical branches of the magnetization characteristic from FIG. 2A), the secondary current is constant and corresponds to magnetization current +i_{μ} or −i_{μ}. The magnitude of magnetization current i_{μ} depends on the width of the hysteresis in the magnetization characteristic, which corresponds to the coercivity field strength H_{C}; i.e., i_{μ}=1_{FE}/N·H_{C}. As soon as the magnetization in core 10 has reached the positive or negative saturation magnetization, secondary current i_{S} starts to increase, as already described above. Due to the symmetry of the hysteresis characteristic, the temporal course of secondary current i_{S} is also symmetric according to a central current value.

FIGS. 3A and 3B show the same situation as FIGS. 2A and 2B, but for a primary current i_{P} that is not equal to zero. The magnetic field generated by primary current i_{P} is additively superposed in soft magnetic core 10 on the magnetic field of secondary current i_{S}, which can be represented as a shift of the magnetization characteristic along the abscissa. This situation is illustrated in FIG. 3A. The corresponding temporal course of the secondary current is represented in FIG. 3B. The secondary current is similar as shown in FIG. 2B, corresponding to a primary current of zero, except that the secondary current is no longer symmetric around the abscissa (i_{S}=0); instead, it is symmetric around another horizontal line (i_{S}=i_{P}/N). This means that during remagnetization, the primary and secondary currents are in the same relation (k=1:N) as the winding numbers of primary winding 1 and secondary winding 2, except for the hysteresis offset in the level of magnetization current i_{μ}. For the current measurement, secondary current signal i_{S}, or, more precisely, current signal u_{SH} at shunt resistor R_{SH}, is sampled during the remagnetization process. By sampling the secondary current signal in the first half of the secondary current period (of a measurement cycle), one obtains the current measurement value i_{S}[n−1]=(i_{P}/N)+i_{μ}; in the second half of the period, one obtains the current measurement value i_{S}[n]=(i_{P}/N)−i_{μ}. By averaging, the hysteresis error caused by the magnetization current can be eliminated; the primary current at sampling time n is calculated as follows:

i_{P}[n]=N·(i_{S}[n−1]=i_{S}[n])/2. (3)

Since the hysteresis of the magnetization characteristic has no influence on the measurement result, this current measurement procedure is well suited for measuring very small currents. The measurement range extends from a few milliamps to several kiloamps. During the remagnetization process in core 10, secondary current i_{S} follows primary current i_{P} in accordance with the transfer ratio 1:k. During the remagnetization process, the secondary current is sampled at least once in order to obtain a measured value (i_{S}+i_{μ} or i_{S}−i_{μ}) to calculate the primary current. The sampling can also be carried out repeatedly during remagnetization with a sampling rate that is substantially higher than the oscillation frequency of sensor f_{SENSOR}.

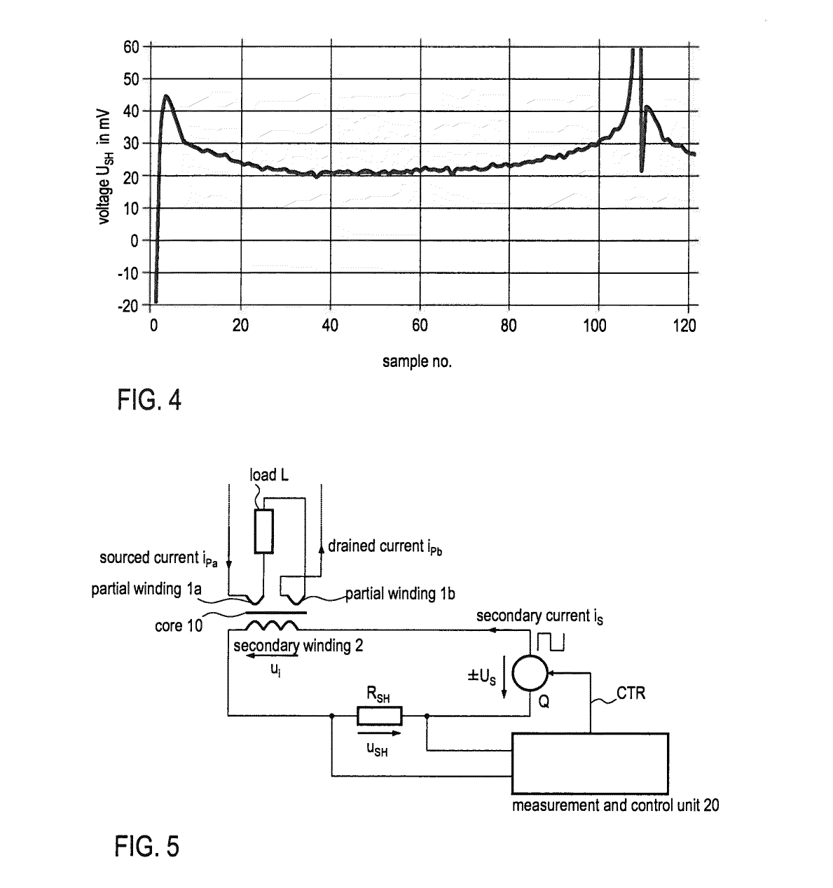

During remagnetization, but before magnetic saturation is achieved in core 10, secondary current i_{S} is approximately constant and equal to (i_{P}/N)±i_{μ}. The situation represented in FIG. 3b is, however, idealized. In practice, the secondary current during remagnetization but before magnetic saturation is achieved in core 10 is not constant; it instead has a curved course, as represented in FIG. 4. The curved pattern is explained, alongside other factors, by the fact that the magnetization characteristic (hysteresis characteristic) of the magnetic core is not exactly rectangular. The exact shape of the current course, as well as duration Δt₋ of the remagnetization process (between negative and subsequent positive saturation), depends on the value of the primary current. Time period Δt₋ is approximately 108 sampling periods in FIG. 4. More precise analyses have shown that not all arbitrarily selected sampling values of these 108 are suitable for an exact determination of primary current i_{P}. Below, an assessment method is described by means of which the systematic measurement error can largely be avoided and the precision of the current measurement can be increased.

The measurement principle explained so far in reference to FIGS. 1 to 3, with only minor modification of the sensor design shown in FIG. 1, can also be used for the differential current measurement. Differential current measurements are used, for example, in residual-current circuit breakers. For this purpose, instead of primary winding 1, first partial winding 1a and second partial winding 1b are connected to core 10. The primary current through first partial winding 1a is denoted as i_{Pa} and the primary current through the second partial winding 1b is denoted as i_{Pb}. The partial windings may also comprise only a single winding in each case; they are oriented in such a manner that the magnetic fields caused by currents i_{Pa} and i_{Pb} compensate for each other at least partially (destructive superposition), and only the net primary current i_{Pa}−i_{Pb} generates a corresponding net magnetic field in core 10 (which is again superposed by the magnetic field of secondary current i_{S}). The mentioned modified sensor design is represented in FIG. 5; apart from primary winding 1, it is substantially identical to the design in FIG. 1. The course of secondary current i_{S} represented in FIG. 4 can also be observed in the differential current sensor according to FIG. 5. In the example shown in FIG. 5, the two partial windings 1a and 1b are upstream or downstream of load L so that the difference i_{Pa}−i_{Pb} is not equal to zero only if a stray current that corresponds precisely to this difference flows off from the load. The differential current is calculated from the sampling values of the secondary current analogous to equation 3 as follows:

Δi_{P}[n]=i_{Pa}[n]−i_{Pb}[n]=N·(i_{S}[n−1]+i_{S}[n])/2. (4)

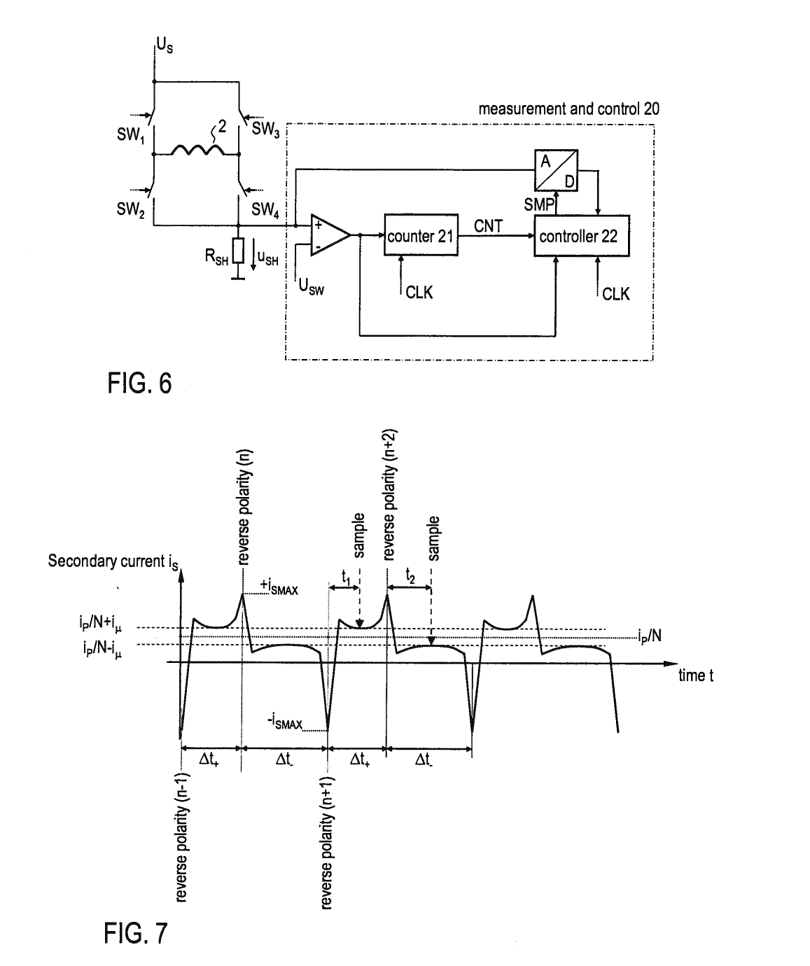

The course of secondary current i_{S} represented in FIG. 4 shows that, with regard to the precision of the current measurement, it matters when secondary current i_{S} is sampled in time intervals Δt₊ and Δt₋ (see FIG. 2B) in order to obtain sampling values i_{S}[n] and i_{S}[n−1] (see equation 3). Investigations have shown that primary current i_{P}[n], calculated according to equation 3, and primary current difference Δi_{P}[n], calculated according to equation 4, can be determined very precisely if the sampling times when the secondary current is sampled are selected to be approximately in the center of time intervals Δt₊ and Δt₋ (see FIG. 2B and FIG. 7). Here it should be noted that these time intervals are not constant, but depend on the value of the secondary current, which is problematic in the case of the differential current measurement particularly since the value of secondary current i_{S} can vary greatly, even in the case of approximately constant differential current Δi_{P}[n]. The sampling time thus has to be adaptively adjusted to the period duration of the sensor oscillation. An example of a circuit with adaptive sampling time adjustment is explained below in reference to FIGS. 6 and 7.

The sensor arrangement represented in FIG. 6 corresponds in many parts to the sensor arrangement in FIG. 5. Voltage source Q (represented in FIG. 5), whose polarity can be reversed, is implemented in FIG. 6 as an H bridge that consists of four controllable semiconductor switches SW₁, SW₂, SW₃ and SW₄, or four MOSFETs. When switches SW₁ and SW₄ are actuated so that they conduct and switches SW₂ and SW₃ are actuated so that they do not conduct, a positive voltage is applied to secondary winding 2. When switches SW₂ and SW₃ are actuated so that they conduct and switches SW₁ and SW₄ are actuated so that they do not conduct, a negative voltage is applied to secondary winding 2. The associated control signals are generated, for example, by control unit 22 and are optionally amplified by means of driver circuits (not represented). The half bridge is connected between a first supply connection, to which supply voltage U_{S} is applied, and a second supply connection, to which reference potential GND is connected. Measurement resistor R_{SH} is series-connected to the half bridge so that voltage U_{SH} through resistor R_{SH} depends on secondary current i_{S}. In the present example, U_{SH}=i_{S}·R_{SH}.

When the magnetic core is saturated, the secondary current increases (see also FIG. 2B) and the polarity of the voltage through secondary winding 2 is reversed. The achievement of the (positive and negative) saturation is detected when secondary current i_{S} has reached a predetermined maximum value i_{SMAX} or minimum value i_{SMIN} (wherein i_{SMIN}=−i_{SMAX}, for example). This is the case when voltage drop U_{SH} through measurement resistor R_{SH} has reached or exceeded threshold U_{SW}. This condition (U_{SH}≧U_{SW}) can be assessed by means of comparator K in which voltage U_{SW}, representing the threshold, and current measurement signal U_{SH} are supplied. The logic level at the output of comparator K indicates whether threshold U_{SW} (i.e., ±i_{SMAX}) has been reached or exceeded. Reaching the maximum or minimum value ±i_{SMAX} with secondary current i_{S} can be referred to as a “saturation event”, which is detected by means of comparator K.

The output of comparator K is connected to counter 21, which is configured to determine the time between the two successive saturation events (corresponding to Δt₊ and Δt₋ in FIG. 2B and FIG. 7). Clock signal CLK is also applied to counter 21, and the aforementioned time between two successive saturation events is represented by counter reading CNT, which indicates the time as a multiple of period duration T_{CLK} of the clock signal. Counter reading CNT thus always indicates the time between the last detected saturation event and the saturation event detected before that. Counter reading CNT and clock signal CLK are supplied to control unit 22. Control unit 22 is configured to calculate the sampling times from the determined counter readings. Assuming counter reading CNT[n]=y and counter reading CNT[n−1]=x (n is a consecutive index counting the saturation events), then Δt₁=y·T_{CLK} and Δt₋=x·T_{CLK}, and the sampling times for the following periods n+1 and n+2 are t₁=(y/2)·T_{CLK} and t₂=(x/2)·T_{CLK}. This means that secondary current i_{S} is sampled after delay time t₁ (x clock cycles T_{CLK}) following saturation event n+1 and after delay time t₂ (y clock cycles T_{CLK}) following saturation event n+2 (see FIG. 7). Counter readings x and y are updated continuously, as are the resulting delay times t₁ and t₂. The sampling can be shifted by offset z (positive or negative); i.e., t₁=(y/2+z)·T_{CLK,}t₂=(x/2+z)·T_{CLK} (offset not represented in FIG. 7). Control unit 22 is configured to generate corresponding trigger signals for analog-digital converter 23, which generates from analog current measurement signal U_{SH} corresponding digital values from which, in accordance with equations 3 and 4, a measurement value for primary current ip or primary current difference i_{Pa}−i_{Pb} can be calculated.

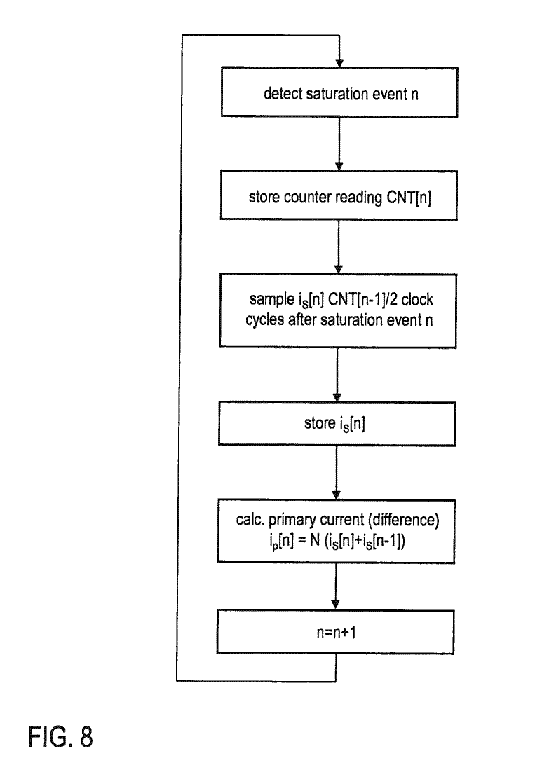

The function of the sensor arrangement according to FIG. 6 (i.e., the method for assessing the secondary current signal) is summarized again based on the sequence diagram represented in FIG. 8. As already mentioned, index n denotes the consecutive saturation events (saturation of the magnetic core in positive or negative directions); the saturation events are detected continuously. Process steps 31 to 36 represented in FIG. 8 are thus repeatedly carried out in a loop. The current loop pass has index n. In step 31, a saturation event (with index n) is detected, and the associated time (Δt₊ or Δt₋) between this saturation event and the previous saturation event (with index n−1) is detected. In the represented example, counter reading CNT[n] of counter 21 (see FIG. 6) is read and stored by control unit 21 for this purpose (step 32). Counter reading CNT[n] represents, for example, the time interval Δt₊, whereas counter reading CNT[n−1] determined in the previous loop pass represents time interval Δt₋.

In step 33, secondary current i_{S} is sampled after a delay time (depending on the previously determined time interval Δt₋) following the last saturation event (with index n). This delay time is designated t₁ or t₂ in FIG. 7. In the present example, the sampling occurs precisely in the center of time interval Δt₋, CNT[n−1]/2 clock periods T_{CLK} after the detected saturation event with index n (i.e., t₂=CNT[n−1]/2). In step 34, sampling value i_{S}[n] is stored. In step 35, primary current i_{P}[n] (or a primary current difference) is calculated from current sampling value i_{S}[n], and sampling value i_{S}[n−1] is stored in the previous loop pass according to equation 3 or 4. In step 36, shown in FIG. 4, index n is incremented and the loop starts from the beginning. In the described procedure, only the last two counter readings CNT[n] and CNT[n−1], as well as the last two sampling values i_{S}[n] and i_{S}[n−1], have to be stored. Older counter readings and sampling values may be discarded.

The embodiment examples described herein represent numerous other possible embodiment examples that also are covered by the scope of protection of the appended claims. The features described in connection with an embodiment example can also, if technically possible and not explicitly excluded, be combined with features of other embodiment examples. It is understood that the components used in the described circuit arrangements can be replaced by other components that substantially fulfill the same function or a similar function. For example, certain functions can thus be implemented by similar electronic components, by digital electronic components or by software implemented in a microcontroller. Mixed forms of analog and digital electronics and software are also possible. The described process steps relate substantially to one of many possible procedures. In addition, the described sequence of steps is not necessarily compulsory.

1. A current sensor arrangement for measuring an effective primary current (i_{P}) in a primary conductor; the current sensor arrangement comprising:
a magnetic core for magnetically coupling the primary conductor to a secondary conductor;
a controlled voltage source coupled to the secondary conductor and configured to apply a voltage (±U_{S}) with adjustable polarity to the secondary conductor so that a secondary current (i_{S}) flows through the secondary conductor;
a measurement and control unit coupled to the secondary conductor and configured to generate a measurement signal (u_{SH}) that represents the secondary current for continuously detecting a magnetic saturation of the core and, in the case of detection of a magnetic saturation of the core, for switching the polarity of the voltage (±U_{S}) in order to reversely magnetize the core,
wherein the measurement and control unit is further configured to sample the measurement signal (u_{SH}) after a delay time (t₁, t₂) following each detection of a magnetic saturation of the core, wherein the delay time is adjusted adaptively depending on a previously determined time period (Δt_{+,} Δt₋) between two successive times when magnetic saturation of the core has been detected.

2. The current sensor arrangement of claim 1, wherein the primary conductor comprises a first part and a second part, through each of which a first and a second primary current flows in such a manner that the magnetic field strength generated by the primary conductor corresponds to the difference of the primary currents.

3. The current sensor arrangement of claim 1, wherein a magnetic saturation in the core is detected when the secondary current reaches a defined maximum or minimum value.

4. The current sensor arrangement of claim 1, wherein the measurement and control unit is configured to continuously determine a first time period (Δt₊) between a first time when a negative saturation is detected and a second time when a positive saturation is detected, wherein, after an additional detection of a negative saturation, the secondary current is sampled, and the delay time between the negative saturation and the sampling of the secondary current depends on the first time period.

5. The current sensor arrangement of claim 4, wherein the delay time between the negative saturation and the sampling of the secondary current is half of the first time period (Δt₊), including a temporal offset.

6. The current sensor arrangement of claim 1, wherein the measurement and control unit is configured to continuously determine a second time period (Δt₋) between a third time when a positive saturation is detected and a fourth time when a negative saturation is detected, wherein, after an additional detection of a positive saturation, the secondary current is sampled and the delay time between the positive saturation and the sampling of the secondary current depends on the second time period.

7. The current sensor arrangement of claim 6, wherein the delay time between the positive saturation and the sampling of the secondary current is half of the second time period (Δt₋), including a temporal offset.

8. The current sensor arrangement of claim 1, wherein the primary current is calculated from the average of two successive sampling values of the measurement signal.

9. A method for measuring a primary current by means of a fluxgate current sensor arrangement that has a primary conductor and a secondary conductor magnetically coupled via a magnetic core; the method comprising:
continuously detecting magnetic saturation in the core;
reversing of the polarity of a supply voltage applied to the secondary conductor when magnetic saturation has been detected;
continuously determining the time period between two successive detections of a magnetic saturation in the core;
sampling a secondary current through the secondary conductor after a delay time following the detection of a magnetic saturation;
adjusting the delay time depending on a previously determined time period between two successive detections of a magnetic saturation in the core.

10. The method of claim 9, wherein the primary conductor comprises a first part and a second part, through each of which a first and a second primary current flow so that the magnetic field strength generated by the primary conductor corresponds to the difference of the primary currents.

11. A differential current sensor arrangement for measuring a difference (i_{P}) between a first primary current in a first part and a second primary current in a second part of a primary conductor; the current sensor arrangement comprising:
a magnetic core for the magnetic coupling of the primary conductor to a secondary conductor;
a controlled voltage source connected to the secondary conductor and configured to apply a current (±U_{S}) with adjustable polarity to the secondary conductor so that a secondary current (i_{S}) flows through the secondary conductor;
a measurement and control unit connected to the secondary conductor and configured to generate a measurement signal (u_{SH}) that represents the secondary current for continuously detecting a magnetic saturation of the core and, in the case of detection of a magnetic saturation of the core, for switching the polarity of the voltage (±U_{S}) in order to reversely magnetize the core,
wherein the measurement and control unit is moreover configured to sample the measurement signal (u_{SH}) after a delay time (t₁, t₂) following each detection of a magnetic saturation of the core, wherein the delay time is adjusted adaptively depending on a previously determined time period (Δt_{+,} Δt₋) between two successive times when magnetic saturation of the core has been detected.

12. A residual-current circuit breaker that has a differential current sensor arrangement for measuring a difference (i_{P}) between a first primary current in a first part and a second primary current in a second part of a primary conductor; the current sensor arrangement comprises the following:
a magnetic core for magnetically coupling the primary conductor to a secondary conductor;
a controlled voltage source connected to the secondary conductor and configured to apply a current (±U_{S}) with adjustable polarity to the secondary conductor so that a secondary current (i_{S}) flows through the secondary conductor;
a measurement and control unit connected to the secondary conductor and configured to generate a measurement signal (u_{SH}) that represents the secondary current for continuously detecting a magnetic saturation of the core and, in the case of detection of a magnetic saturation of the core, for switching the polarity of the voltage (±U_{S}) in order to reversely magnetize the core,
wherein the measurement and control unit is moreover configured to sample the measurement signal (u_{SH}) after a delay time (t₁, t₂) following each detection of a magnetic saturation of the core, wherein the delay time is adjusted adaptively depending on a previously determined time period (Δt_{+,} Δt₋) between two successive times when magnetic saturation of the core has been detected.
